(19) United States
(12) Patent Application Publication
(10) Pub. No.: US 2026/0068640 A1
(43) Pub. Date: Mar. 5, 2026

(54) REDUNDANCY METHODS FOR WAFER-SCALE SYSTEMS

(71) Applicant: Volantis Semiconductor Inc., Portland, OR (US)

(72) Inventor: Tapabrata Ghosh, Oakland, CA (US)

(73) Assignee: Volantis Semiconductor Inc., Portland, OR (US)

(21) Appl. No.: 18/815,939

(22) Filed: Aug. 27, 2024

(51) Int. Cl. H01L 23/528; H01L 23/00; H01L 23/498; H01L 23/538; H01L 25/18; H01L 27/06

(52) U.S. Cl. CPC H01L 23/5283; H10D 88/00

(57) ABSTRACT

A wafer-level assembly of chiplets comprising a plurality of groups of chiplets including a first group of chiplets and a second group of chiplets, wherein the first group of chiplets is organized as a first fully-connected configuration, wherein the second group of chiplets is organized as a second fully-connected configuration. The wafer-level assembly of chiplets further comprises a plurality of interconnects including a first interconnect and a second interconnect, wherein the first interconnect couples a first chiplet of the first group of chiplets with a first chiplet of the second group of chiplets, wherein the second interconnect couples a second chiplet of the first group of chiplets with a second chiplet of the second group of chiplets, and wherein the plurality of interconnects is arranged in a mesh configuration.

### BACKGROUND

Wafer-scale integration (WSI) may hold great promise for future high-performance computing systems with benefits of increased performance, higher density, improved power efficiency, and reduced packaging complexity. Despite its potential benefits, WSI may present significant challenges which include low yield, low defect tolerance, and high interconnect complexity.

The background description provided here is for the purpose of generally presenting the context of the disclosure. Unless otherwise indicated here, the material described in this section is not prior art to the claims in this application and are not admitted to be prior art by inclusion in this section.

### BRIEF DESCRIPTION OF DRAWINGS

The examples will be understood more fully from the detailed description given below and from the accompanying drawings, which, however, should not be taken to limit the disclosure to the specific examples, but are for explanation and understanding only.

FIG. 1 is a schematic of a wafer-level assembly of chiplets connected in a fully-connected torus configuration, in accordance with at least one example.

FIG. 2A is a schematic of a wafer-level assembly of chiplets connected in a fat-tree torus configuration, in accordance with at least one example.

FIG. 2B is a schematic of fat-tree configuration, in accordance with at least one example.

FIG. 3 is a schematic of a three-dimensional (3D) architecture of a wafer-level assembly of chiplets connected in a 3D torus configuration by through-silicon via (TSV), in accordance with at least one example.

FIG. 4 is a schematic of a group of chiplets including different types of chiplets in a wafer-level assembly of chiplets, in accordance with at least one example.

FIG. 5 is a schematic of a chiplet having functionality of a graphics processing unit (GPU), in accordance with at least one example.

FIG. 6 is a schematic of a chiplet having functionality of a memory module, in accordance with at least one example.

FIG. 7 is a schematic of a wafer-level assembly of chiplets with redundancy, in accordance with at least one example.

FIG. 8 is a schematic of a wafer-level assembly of chiplets with redundancy, in accordance with at least one example.

FIG. 9 is a schematic of a wafer-level assembly of chiplets on a substrate with one or more bridge dies, in accordance with at least one example.

FIG. 10 is a flowchart of a method of fabricating a wafer-level assembly of chiplets with redundancy, in accordance with at least one example.

### DETAILED DESCRIPTION

Size of an integrated circuit (IC) may generally be limited by reticle limit of a lithography machine, which may generally be much smaller than the size of a wafer upon which chips are made. To build a system with many chips together, wafer-scale integration is used. For example, with 193 nm and extreme ultraviolet lithography (EUV) machines, reticle size is approximately 33 mm×26 mm, while wafer-scale circuits can be made as large as 215 mm×215 mm, or even larger. Substrates larger than wafers may even be used, such as glass panels, which can be as large as 700 mm×700 mm in size, for example.

Two primary approaches of building a wafer-scale IC are a monolithic approach and a chiplet-based wafer-scale approach. In the monolithic approach, chips may be manufactured on a single wafer substrate and wires are grown to connect the chips/reticles. Integration size may be limited to the size of one wafer substrate for the monolithic approach. Other challenges of the monolithic approach include low yield due to high effective chip area and high defect density, and limited heterogeneity because the chips are based on a single manufacturing process and do not use a mix of process technology nodes. The yield issue may be solved by aggressive redundancy, but this approach brings with it various challenges. For example, some architectures may be much harder to make fault-tolerant than others. An alternative approach to make wafer-scale chips may entail using chiplets connecting the chiplets together to form a very large-scale assembly. This may be achieved using a large common substrate, or by using bridge chips or other methods for overlapping dies that are bonded (instead of a single large common substrate).

In the chiplet based wafer-scale approaches, the yield of the bonding events themselves can become an issue. For example, in a case with 64 chiplets, even a 99% bonding yield results in approximately 52% yield at assembly level (0.99\hat{ }64). Redundancy in chiplet based wafer-scale approaches may be expensive for the following reasons. First, the number of chiplets is relatively limited (e.g., an 8×8 array), which means that having row/column redundancy in a mesh network may lose 12.5% of the total chiplets because increasing the number of chiplets to mitigate failures may adversely impact the yield as there are more bonding events to attach chiplets together. Second, skipping a chiplet node in a wafer-scale system would mean increasing the effective wire length (e.g., by approximately 25 mm), which may massively increase the required electrical wire signal energy. Third, software view of a logical mesh may break by having a “hole” in the mesh where there is a faulty chip/chiplet. This hole may cause software compilation issues. Bypassing a single node in a mesh or torus configuration without a row/column spare node may result in a different logical topology, which creates software programmability challenges.

Described herein is a method and apparatus for creating an efficient redundancy scheme to increase yield in certain types of wafer-scale systems. For wafer-scale systems where chiplets are bonded to create a larger than reticle assembly, the bonding of chiplets to a substrate or other chiplets can fail due to systematic failures causing all the bumps in a chiplet to fail to bond, or from an excessive number of individual bump failures. When this happens, the wafer-scale assembly may become useless and is discarded. At least one example discloses a hierarchical network topology to allow for efficient redundancy for such systems, and to allow for increased yields at low overheads.

Here, a “chiplet” may generally refer to an IC or a die that is designed to operate as part of a larger system-on-chip (SoC) architecture. Instead of creating a complete custom chip from scratch, manufacturers can use multiple chiplets or dies, each designed for specific functions, and integrate them into a single package or die. Chiplets allow for modular design, which can improve efficiency and reduce manufacturing costs. This approach also provides flexibility, as different chiplets can be combined in various configurations to meet the demands of different applications. Chiplets can vary in function, including processing cores, memory controllers, or specific I/O functionalities. Chiplets can be used in high-performance computing and edge devices, as they enable quicker time-to-market and the ability to mix and match to create optimized solutions.

The methods and apparatuses of some examples are implementable for homogeneous or heterogeneous chiplets to be integrated on wafer-scale systems. In at least one example, redundancy is achieved through a combination of fully-connected, fat-tree, mesh, or torus topologies.

Here, a “fully-connected topology” generally refers to a type of network configuration where every node (device) in the network is directly connected to every other node. This means that for a network with n nodes, there are a total of n(n−1)/2 direct connections or links. Each device can communicate directly with every other device in the network without needing to go through a central hub or switch. If one link fails, the network can still function because there are multiple other paths for communication among devices. Direct connections can lead to lower latency in communication since data can be sent directly to the destination.

Here, a “torus topology” generally refers to a network design for high-performance computing systems and parallel processing environments. A torus topology is an extension of a mesh topology, wherein nodes are connected in a grid-like pattern, with an additional wrap-around connection that forms a closed loop, resembling a torus (doughnut) shape. In at least one example, the torus topology may provide multiple redundant paths between the components, enhance fault tolerance and reduce network congestion. Having a multidimensional design, a torus topology can be constructed by arranging components or groups of components in a multi-dimensional grid, wherein each dimension is cyclically connected. In a torus topology, components or groups of components on edges of a grid are connected to the components or groups of components on the opposite edge. This may create a continuous loop in each dimension, reducing the diameter of the network. Torus topologies can be designed in multiple dimensions (e.g., one dimensional (1D), two-dimensional (2D), three-dimensional (3D), or even higher).

In a 2D torus topology, each node has four direct neighbors, while in a 3D torus topology, each node has six direct neighbors (two in each dimension). In an n dimensional (nD) torus topology, each node has 2×n direct neighbors. The wrap-around connections may decrease the network diameter, allowing data to travel across the network in fewer hops compared to a regular mesh. Torus topology may reduce latency and improve communication efficiency. Multiple paths between any two nodes may provide redundancy, enhancing fault tolerance. If one path fails, data may be rerouted through alternative paths, maintaining network reliability. Torus topologies may be easily scaled by adding more nodes or dimensions. Higher-dimensional tori (e.g., 3D, 4D, etc.) may offer even greater scalability and performance, making them suitable for large-scale systems. Regular structure of a torus topology may ensure uniform bandwidth across the network, preventing bottlenecks and allowing consistent data flow. Adaptive routing algorithms may distribute traffic evenly across the network, balancing the load and preventing congestion hotspots.

Here, “fat-tree network topology” may generally refer to a configuration of nodes with multiple layers, including core (or root), aggregation, and edge (or leaf) layers. Each layer may be connected to the layers above and below it. In a two-layer fat-tree network topology of chiplets (or nodes), a core layer in the hierarchy may comprise of one or more root-chiplets (e.g., root node), whereas an edge layer may comprise of one or more leaf-chiplets (e.g., leaf nodes). The bandwidth of the interconnects may increase towards the core layer. In at least one example, root-chiplets or core switches may have higher capacity connections compared to leaf-chiplets or edge switches. Fat-tree network topology may balance the network load and avoid bottlenecks. The fat-tree connectivity topology may provide redundancy by providing multiple paths between any two nodes in a network. In case of failure of a link or a chiplet, traffic may be rerouted through alternative paths by software, thereby enhancing fault tolerance and reliability. More switches and links may be added to a fat-tree network topology of chiplets to accommodate more chiplets thereby allowing scalability of the network without significant changes to the overall network structure. Groups of chiplets may be connected in a fat-tree network topology inside the group. Intergroup connectivity may be a mesh or a torus. A fat-tree network topology may be used in data centers and large-scale distributed systems. A fat-tree topology may improve network performance and scalability by providing redundancy and higher bandwidth.

Disclosed herein is a family of network topologies and their application to wafer-scale integrated systems, especially with regards to efficient redundancy methods. In at least one example, the family of network topologies is a hierarchical topology, where an intra-group topology is a low or medium diameter topology that is not a mesh or torus, and an inter-group topology is a mesh or torus. In at least one example, the intra-group topology is a fully-connected topology, and the inter-group topology is a mesh or torus. In at least one example, the intra-group topology is a fat-tree topology (folded Clos), and the inter-group topology is a mesh or torus topology. In implementations of such a topology in wafer-scale systems, the intra-group connections may be implemented using low-swing electrical signals that may be well suited for medium distance connections (e.g., less than 40 mm).

In the topologies herein, redundancy may be relatively cheap to achieve since the logical topology may be maintained by devoting one spare node within each group. The intra-group topology of a fully connected graph may accommodate an extra node, since a physical topology that is a fully connected graph, of 8 nodes, for example, can show a logical topology view to the architecture or software (SW) stack of a fully connected graph of 7 nodes, for example, with one of them being a spare node. In this manner, many failed nodes can be tolerated. Although the primary mechanism of failure may be bonding related failures at manufacturing time, the disclosed scheme is not limited to tolerating failures of that kind. Other failures, such as test escapes (e.g., bad “known good die”), or even failures as a function of time (e.g., aging related failures) can also be tolerated.

Different parameters may result in different connectivities between the groups. Changing different network parameters may result in a greater number of connections between the groups. This might be preferable for greater redundancy as well as greater connectivity for increased bandwidth and other performance parameters. Electrical signals may be well suited for relatively short distance connections. For instance, the intra-group topology may typically be dispersed over a relatively small area, thus making for short wires, while the inter-group topology may be a mesh or torus configuration, which features short wires by design.

A variety of different implementations for such topologies may be possible in a wafer-scale integrated system. Some examples may have active network elements built into an interposer substrate. There is a wide spectrum of such active network elements, from router elements to low swing signaling circuits. For instance, spine nodes in a fat-tree configuration in the topology can be embedded into the interposer substrate.

In the following description, numerous details are discussed to provide a more thorough explanation of examples of the present disclosure. It will be apparent, however, to one skilled in the art, that examples of the present disclosure may be practiced without these specific details. In other instances, well-known structures and devices are shown in block diagram form, rather than in detail, to avoid obscuring examples of the present disclosure.

Note that in the corresponding drawings of the examples, signals are represented with lines. Some lines may be thicker, to indicate more constituent signal paths, and/or have arrows at one or more ends, to indicate primary information flow direction. Such indications are not intended to be limiting. Rather, the lines are used in connection with one or more exemplary examples to facilitate easier understanding of a circuit or a logical unit. Any represented signal, as dictated by design needs or preferences, may actually comprise one or more signals that may travel in either direction, and may be implemented with any suitable type of signal scheme.

It is pointed out that those elements of the figures having the same reference numbers (or names) as the elements of any other figure can operate or function in any manner like that described but are not limited to such.

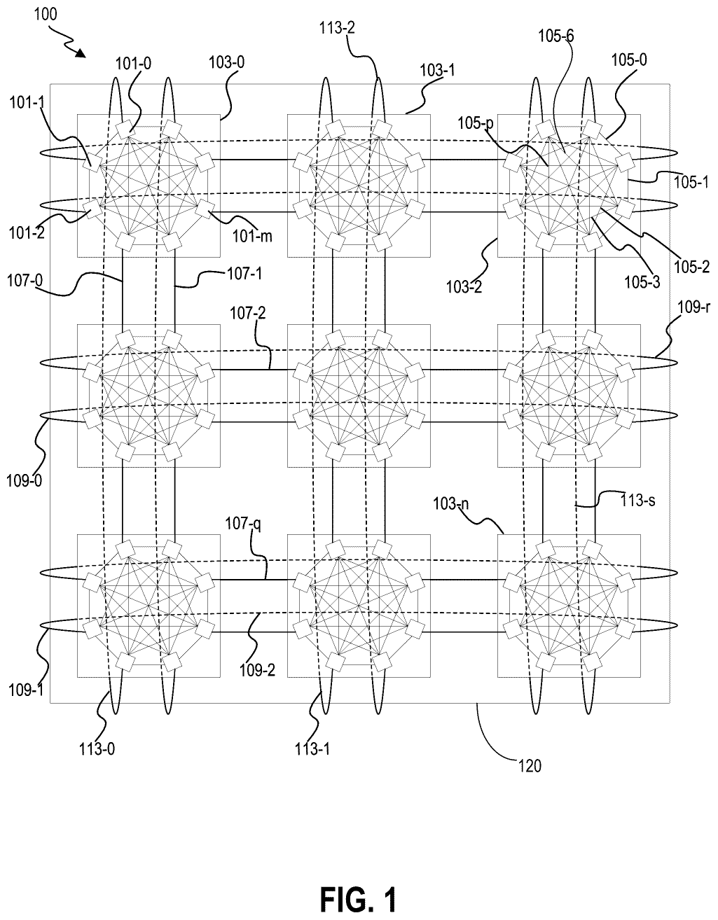

FIG. 1 is a schematic of a wafer-level assembly 100 of chiplets connected in a fully-connected torus configuration, in accordance with at least one example. Wafer-level assembly 100 includes wafer scale integration (WSI) of chiplets. In at least one example, chiplets 101-0, 101-1, . . . , 101-m are connected in groups of chiplets 103-0, 103-1, 103-2, . . . , 103-n. Chiplets such as 101-0, 101-1, . . . , or 101-m may be generally referred to as chiplets 101. Groups of chiplets such as 103-0, 103-1, 103-2, . . . , or 103-n may be generally referred to as groups of chiplets 103. In at least one example, the intragroup connections (e.g., local connections) among the chiplets within a group of groups of chiplets 103 are interconnects 105-0, 105-1, 105-2, . . . , 105-p. Interconnects such as 105-0, 105-1, 105-2, . . . , or 105-p may be generally referred to as interconnects 105. In at least one example, the chiplets in a group of groups of chiplets 103-0, 103-1, 103-2, . . . , 103-n are connected in a fully-connected configuration through interconnects 105-0, 105-1, 105-2, . . . , 105-p.

In at least one example, groups of chiplets 103-0, 103-1, 103-2, . . . , 103-n may be connected in a mesh or torus topology. In at least one example, intergroup connections 107-0, 107-1, 107-2, . . . , 107-q (e.g., global connections) among groups of chiplets 103-0, 103-1, 103-2, . . . , 103-n interconnect groups of chiplets 103-0, 103-1, 103-2, . . . , 103-n in a mesh topology. In at least one example, a column of groups of groups of chiplets 103-0, 103-1, 103-2, . . . , 103-n on the right edge is connected to columns of groups of groups of chiplets 103-0, 103-1, 103-2, . . . , 103-n at the left edge through interconnects 109-0, 109-1, 109-2, . . . , 109-r. In at least one example, a row of groups of groups of chiplets 103-0, 103-1, 103-2, . . . , 103-n at the top edge is connected to a row of groups of groups of chiplets 103-0, 103-1, 103-2, . . . , 103-n at the bottom edge through interconnects 113-0, 113-1, 113-2, . . . , 113-s, to interconnect groups of chiplets 103 in a torus configuration. In at least one example, groups of chiplets 103-0, 103-1, 103-2, . . . , 103-n are interconnected in a 2D torus configuration, in which every group of groups of chiplets 103-0, 103-1, 103-2, . . . , 103-n is connected to four adjacent groups of groups of chiplets 103-0, 103-1, 103-2, . . . , 103-n.

In at least one example, groups of chiplets 103-0, 103-1, 103-2, . . . , 103-n are mounted on a substrate 120. In at least one example, substrate 120 includes a redistribution layer (RDL) with embedded interconnects to interconnected groups of chiplets 103-0, 103-1, 103-2, . . . , 103-n. In at least one example, substrate 120 includes active or passive devices. In at least one example, substrate 120 is an interposer providing electrical connections between different chiplets 101-0, 101-1, . . . , or 101-m or different groups of chiplets of groups of chiplets 103-0, 103-1, 103-2, . . . , 103-n. In at least one example, the interposer acts like a miniature printed circuit board (PCB), facilitating high-bandwidth connectivity and short-distance point-to-point paths between different 101-0, 101-1, . . . , or 101-m or groups of chiplets 103-0, 103-1, 103-2, . . . , 103-n. In at least one example, substrate 120 as an interposer handles other functions such as external input/output (I/O) interfaces, power distribution, and system management, etc.

In at least one example, groups of chiplets 103 may be homogenous or heterogenous. A homogenous group may contain chiplets made with the same process technology, for example, complementary metal-oxide-semiconductor (CMOS). A heterogenous group may contain chiplets made with different technologies, for example, some chiplets may be fabricated with transistor-transistor logic (TTL) technology and others with CMOS technology, some chiplets may be from different technology CMOS nodes. A group of chiplets of groups of chiplets 103-0, 103-1, 103-2, . . . ,103-n may include chiplets of a same functionality or may include chiplets of different functionalities.

At least for one example, chiplets 101-0, 101-1, . . . , 101-m in a group of chiplets of groups of chiplets 103-0, 103-1, 103-2, . . . , 103-n are microprocessors. At least for one example, chiplets 101-0, 101-1, . . . , 101-m in a group of chiplets of groups of chiplets 103-0, 103-1, 103-2, . . . , 103-n are graphical processing units (GPUs). In at least one example, chiplets 101-0, 101-1, . . . , 101-m in a group of chiplets of groups of chiplets 103-0, 103-1, 103-2, . . . , 103-n are functionally different from each other. For instance, the chiplet 101-0 may be a microprocessor, chiplet 101-1 may be a GPU, chiplet 101-2 may be a local area network (LAN) port, chiplet 101-3 may be a double data rate (DDR) based random access memory (RAM), etc.

In at least one example, a chiplet of chiplets 101-0, 101-1, . . . , or 101-m is an input or output device, sensor or port (e.g., a video graphics array (VGA) port, a universal serial bus (USB) port, a PS/2 port, a Wi-Fi port, an analog-to-digital converter (ADC), a digital-to-analog converter (DAC), a bridge input port, a thermocouple port, a thermistor port, an H-bridge driver, a pressure sensor, an accelerometer, a gyroscope, or a microphone, etc.).

In at least one example, chiplets 101-0, 101-1, . . . , or 101-m in a group of chiplets 103-0, 103-1, 103-2, . . . , 103-n may be connected in a fat-tree (folded Clos) topology. In chiplet-based designs, fat-tree topology may be used to organize and interconnect multiple chiplets. Fat-tree interconnect topology may reduce the distance data needs to travel, may improve communication efficiency, and may reduce latency. Fat-tree interconnected structures may provide redundancy, ensuring that if one path fails, data may be rerouted through another path. A fat-tree topology having multiple root-chiplets may reduce the dependency of a network on any single root-chiplet. If one root-chiplet fails, another root-chiplet may be configured to take over data transmission function of the failed root-chiplet, thereby enhancing fault tolerance.

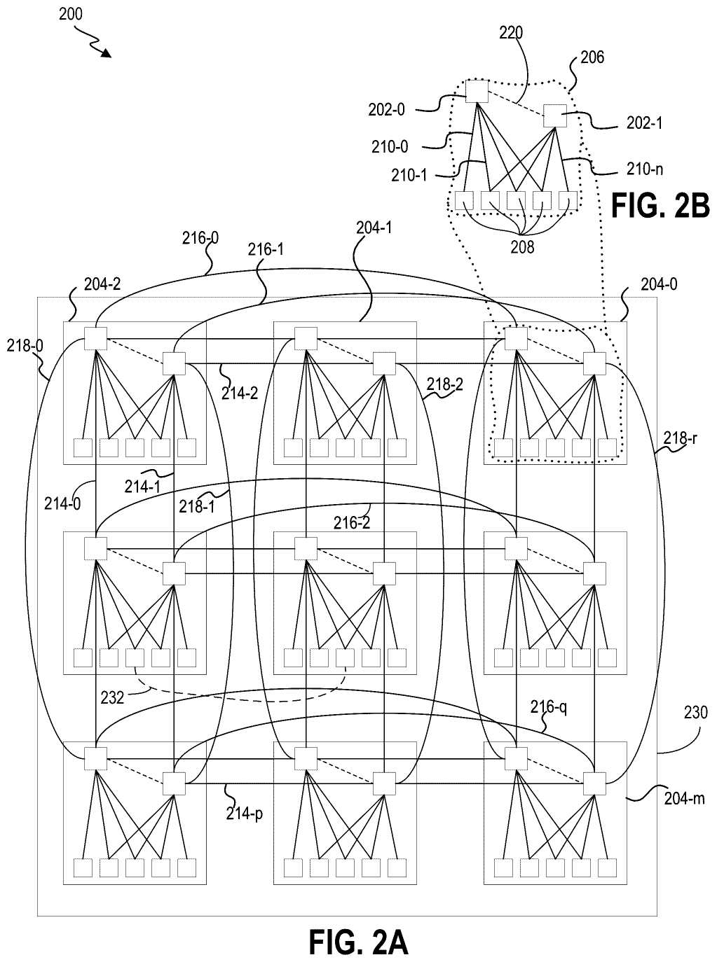

FIG. 2A is a schematic of a wafer-level assembly 200 of chiplets connected in a fat-tree torus configuration, in accordance with at least one example. FIG. 2B is a schematic of fat-tree configuration, in accordance with at least one example. Wafer-level assembly 200 is another architecture of a WSI of chiplets. In at least one example, a wafer-level assembly 200 includes chiplets 208 connected in groups of chiplets 204-0, 204-1, 204-2, . . . , 204-m. Groups of chiplets such as 204-0, 204-1, 204-2, . . . , or 204-m may be generally referred to as groups of chiplets 204. In at least one example, the intragroup connections (local connections) among the chiplets 208 within a group of chiplets of groups of chiplets 204 are interconnects 210-0, 210-1, 210-2, . . . , 210-n. Interconnects such as 210-0, 210-1, 210-2, . . . , or 210-n may be generally referred to as interconnects 210. In at least one example, chiplets 208 in a group of chiplets of groups of chiplets 204 are connected in a fat-tree topology (hierarchically connected graph) through interconnects 210. In at least one example, fat-tree topology starts with a single root-chiplet 202-0, which branches out to leaf-chiplets 208. In at least one example, fat-tree topology starts with more than one root-chiplet 202-0, 202-1, etc. (herein generally referred to as root-chiplet 202). In at least one example, root-chiplets 202 are not internally connected inside a group of chiplets of groups of chiplets 204-0, 204-1, 204-2, . . . , 204-m. In at least one example, root-chiplets 202 are internally connected inside a group of chiplets of groups of chiplets 204-0, 204-1, 204-2, . . . , 204-m through interconnect 220. In at least one example, leaf-chiplets 208 may further branch out to their own leaf-chiplets, which may create a hierarchical structure.

Each level of fat-tree topology 206 may represent a different layer of nodes, with the root-chiplets 202 at the top and leaf-chiplets 208 at the bottom. In at least one example, root-chiplets 202 may act as the central hubs for communication, managing data flow to and from leaf-chiplets 208 which may centralize control by simplifying management of data traffic and may reduce latency for critical communications. In at least one example, groups of chiplets 204 may be connected in a mesh or torus topology through root-chiplets 202. In at least one example, intergroup connections (global connections) 214-0, 214-1, 214-2, . . . , 214-p among groups of chiplets 204 interconnect groups of chiplets 204 in a mesh topology. Intergroup connections such as 214-0, 214-1, 214-2, . . . , or 214-p may be generally referred to as intergroup connections 214.

In at least one example, a column of groups of chiplets of groups of chiplets 204 on the right edge is connected to a column of groups of chiplets of groups of chiplets 204 on the left edge through interconnects 216-0, 216-1, 216-2, . . . , 216-q. In at least one example, a row of groups of chiplets of groups of chiplets 204 at the top edge is connected to a row of groups of chiplets of groups of chiplets 204 at the bottom edge through interconnects 218-0, 218-1, 218-2, . . . , 218-r, to interconnect groups of chiplets 204 in a torus configuration. Interconnects such as 216-0, 216-1, 216-2, . . . , or 216-q may be generally referred to as interconnects 216. Interconnects such as 218-0, 218-1, 218-2, . . . , or 218-r may be generally referred to as interconnects 218.

In at least one example, groups of chiplets 204 are interconnected in a 2D torus configuration, in which every group of chiplets of groups of chiplets 204 is connected to four adjacent groups of chiplets of groups of chiplets 204. In at least one example, some of leaf-chiplets 208 in one group of chiplets of groups of chiplets 204 may be connected through interconnects 232 to some leaf-chiplets 208 in another group of chiplets of groups of chiplets 204 to provide additional redundant connectivity. This interconnection topology may reduce the distance data needs to travel from one chiplet to another, may improve communication efficiency, and may reduce latency. The interconnected structure provides redundancy, ensuring that if chiplet fails, data can be rerouted through another chiplet. In at least one example, by interconnecting root-chiplets 202, the network communication dependency on any single root-chiplet 202 is eliminated. If one root node 202 fails, others can take over its functions, enhancing fault tolerance.

In at least one example, groups of chiplets 204 are mounted on a substrate 230. In at least one example, substrate 230 includes a redistribution layer (RDL) with interconnects to couple various groups of chiplets 204. In at least one example, substrate 230 includes active or passive devices. In at least one example, substrate 230 is an interposer providing electrical connections between different chiplets of the chiplets 202, of chiplets 208, or of groups of chiplets 204. In at least one example, the interposer acts like a miniature printed circuit board, facilitating high-bandwidth connectivity and short-distance, point-to-point paths between different chiplets of chiplets 202, of chiplets 208, or of groups of chiplets 204. In at least one example, substrate 230 as interposer handles other functions such as external I/O interfaces, power distribution, and system management.

Groups of chiplets 204 may be homogenous or heterogenous. A homogenous group may contain chiplets made with the same technology, for example, CMOS. A heterogenous group may contain chiplets made with different technologies, for example, some chiplets may be fabricated with TTL technology and others with CMOS technology. A group may include chiplets of the same functionality or may include chiplets of different functionalities. At least for one example, chiplets 208 in groups of chiplets 204 are microprocessors. At least for one example, chiplets 208 in a group of chiplets of groups of chiplets 204 are GPUs. In at least one example, chiplets 208 in a group of chiplets of groups of chiplets 204 are functionally different from each other, for example, some chiplets of chiplets 208 may be microprocessors, others may be GPUs, LAN ports, or DDR3 RAMs, etc.

In at least one example, a chiplet of chiplets 208 is an input or output device, a sensor, or a port, for example, a VGA port, a USB port, a PS2 port, a Wi-Fi port, an ADC, a DAC, a bridge input port, a thermocouple port, a thermistor port, an H-bridge driver, a pressure sensor, an accelerometer, a gyroscope, or a microphone, etc.

In at least one example, intergroup connections 214 help in distributing the communication load, preventing bottlenecks at any single node. In at least one example, root-chiplets 202 act as relay points, exchanging data between root-chiplets 202 of other groups of chiplets of groups of chiplets 204 and between leaf-chiplets 208 in a same group or in different groups of chiplets of groups of chiplets 204. This may help in managing and distributing the data traffic efficiently, ensuring that no single node becomes a bottleneck. By distributing the data transmission load among multiple intergroup connections 214, a single connection of connections 214 may be avoided from being overwhelmed. Intergroup connections 214 may be used to scale the network by adding more nodes at different levels without disrupting the existing structure. In a multi-core processor with chiplets, intermediate connections 214 may be used to manage communication between different cores and memory units.

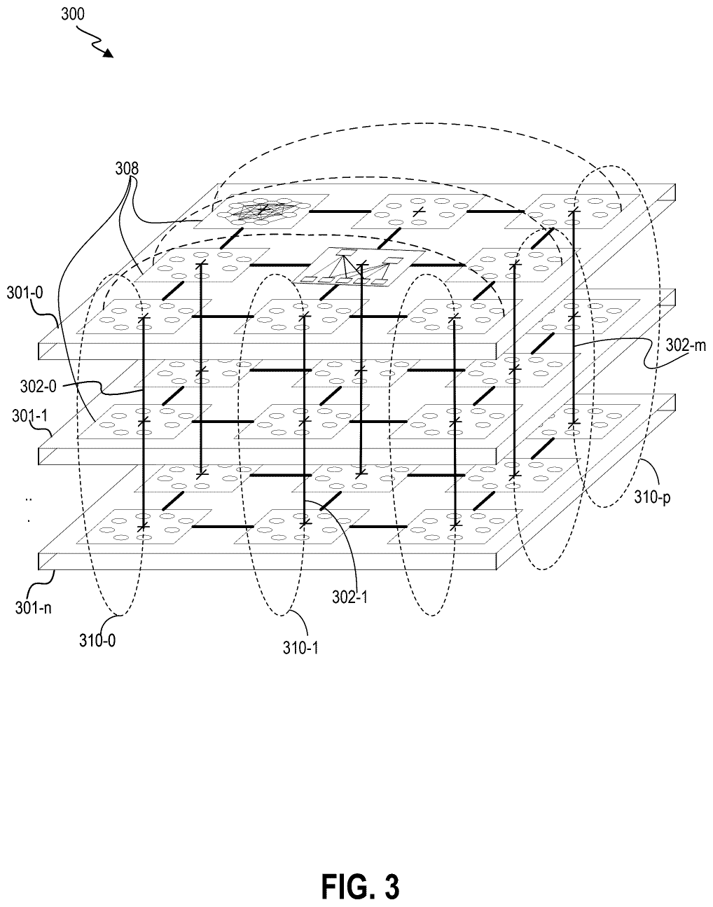

FIG. 3 is a schematic of a 3D architecture 300 of wafer-level assembly of chiplets connected in a 3D torus configuration by through-silicon via (TSV), in accordance with at least one example. In at least one example, 3D architecture 300 includes stacking of wafer-level assemblies 301-0, 301-1, . . . , 301-n that are connected through vertical interconnect such as through-silicon vias (TSVs) 302-0, 302-1, . . . , 302-m, copper-to-copper bonding, copper-to-copper hybrid bonding, etc. A wafer-level assembly such as 301-0, 301-1, . . . , or 301-n may be generally referred to as wafer-level assembly 301. In at least one example, wafer-level assembly 301 may include wafer-level assembly 100 or wafer-level assembly 200.

In at least one example, TSVs 302-0, 302-1, . . . , 302-m are vertical electrical connections that pass through a silicon wafer 301 or may be across the layers. A TSV such as 302-0, 302-1, . . . , or 302-m may be generally referred to as TSV 302. TSV 302 may be utilized to create high-performance interconnect in 3D ICs and packages. In at least one example, wafer-level assembly 301 is stacked vertically with one or more wafer-level assemblies and interconnected by TSV 302. Stacking of wafer-level assemblies 301-0, 301-1, . . . , 301-n may allow for high-density integration and efficient communication between the wafer-level assemblies. TSVs 302 may provide vertical electrical connections through the silicon wafers 301, enabling wafer-level assemblies 301 to function as a cohesive unit. TSVs 302 may enable compact and efficient designs. In at least one example, wafer-level assemblies 301-0, 301-1, . . . , 301-n are connected in a 3D mesh topology. In at least one example, groups of chiplets 308 in a top layer wafer-level assembly are connected to groups of chiplets 308 in a bottom layer wafer-level assembly through interconnects 310-0, 310-1, . . . , 310-p to interconnect wafer-level assemblies 301-0, 301-1, . . . , 301-n in a 3D torus configuration. In at least one example, groups of chiplets 308 are interconnected in a 3D torus configuration, in which every group is connected to adjacent groups (e.g., six adjacent groups).

In the context of wafer-level assemblies 301-0, 301-1, . . . , 301-n on a silicon wafer substrate, a switchless fully-connected or fat-tree topology can be used, in accordance with at least one example. The architecture of some examples leverages wafer-scale integration to eliminate the need for high-radix switches. The architecture of some examples may use distributed high-bandwidth networks-on-chip (NoC) in or on the silicon wafer in wafer-level assemblies 301-0, 301-1, . . . , 301-n. The architecture of some examples enhances local throughput and maintains global throughput, making it a promising solution for future large-scale supercomputers. Local throughput refers to data processing speed within a single node or a specific region of a supercomputer. For example, local throughput may be improved by integrating high-bandwidth memory within or close to a processor thereby reducing latency and increasing data transfer rates, or by leveraging advanced caching mechanisms and memory hierarchies. Global throughput refers to the performance and efficiency of data transfer and processing across an entire supercomputer, including communication between nodes. Global throughput may be improved, for example, by using high-speed network technologies and interconnects, implementing scalable network architectures, such as fat-tree, fully-connected, or hypercube topologies, or optimizing distributed memory access patterns and using advanced algorithms for data distribution.

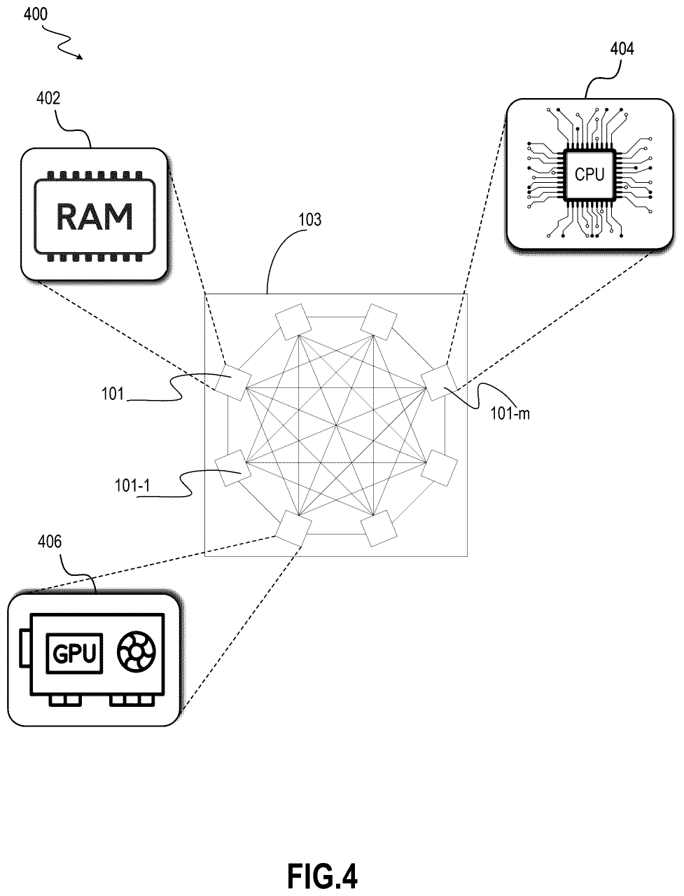

FIG. 4 is a schematic 400 of a group of chiplets including different types of chiplets in a wafer-level assembly of chiplets, in accordance with at least one example. In at least one example, chiplets 101-0, 101-1, . . . , 101-m are interconnected in a fully-connected topology. In at least one example, chiplets 101 are interconnected in a fat-tree topology. In at least one example, group of chiplets 103 may have homogeneous integration. In at least one example, a chiplet 101-0 in a group of chiplets 103-0 of the group of chiplets 103 is directly connected to other chiplets 101-1, . . . , 101-m within the group of chiplets 103-0 of groups of chiplets 103. In at least one example, chiplets 101 are connected in a fat-tree topology 206, wherein group of chiplets 103 may have homogeneous integration. Fat-tree topology 206 may provide interconnections to many leaf-chiplets. In at least one example, chiplets 101 in group of chiplets 103 are functionally similar. In at least one example, chiplets 101 in group of chiplets 103 are fabricated using the same fabrication technology. In at least one example, chiplets 101 in group of chiplets 103 are functionally different from each other. In at least one example, chiplets 101 in group of chiplets 103 are fabricated using different fabrication technologies.

In at least one example, chiplets 101 are memory modules 402 connected in a fully-connected topology or a fat-tree topology. In at least one example, memory modules 402 may store data and instructions temporarily or permanently and may enable quick access to the information needed for operations. Memory modules 402 may include a random-access memory (RAM), a read-only memory (ROM), an erasable programmable read-only memory (EPROM), an electrically erasable programmable read-only memory (EEPROM), a dynamic random-access memory (DRAM), a static random-access memory (SRAM), a cache memory, etc. The choice of memory module 402 may not limit the disclosure.

In at least one example, chiplets 101 are GPUs 406 connected in a fully-connected topology or a fat-tree topology. GPUs 406 may handle and accelerate graphics rendering and parallel processing tasks. GPUs may excel in performing multiple simultaneous calculations, which makes them suitable for large scale data processing.

In at least one example, chiplets 101 are central processing units (CPUs) 404 connected in a fully-connected topology or a fat-tree topology. CPU 404 (that may have one or more processor cores) may process tasks, execute instructions and manage operations of a computer. CPUs 404 may run the operating system or any other software. In at least one example, CPUs are general purpose microprocessors, for example, Intel Core i9-13900K, AMD Ryzen 9 7950X, or Apple M2 Pro, etc. CPUs may be high-performance processors for gaming, content creation, or professional workloads. In at least one example, CPUs 404 are microcontrollers, for example, Microchip PIC16F84A, Atmel ATmega328, STMicroelectronics STM32F103, Texas Instruments MSP430G2553, etc.

In at least one example, group of chiplets 103 may have heterogeneous integration configured using a fully-connected topology or a fat-tree topology. Heterogeneous integration may combine multiple chiplets 101 having varying processing functions and fabrication technologies in one system, thereby allowing to synthesize specific complex functions, increase performance, and decrease cost per function required. Chiplets 101 may be a mix of CPU cores, memory modules, memory controllers, application-specific ICs (ASICs), field programmable gate arrays (FPGAs), GPUs, artificial intelligence (AI) accelerators, I/O controllers, filters, network flow processors (NFPs), serializers/deserializers (SerDes), reduced instruction set computers (RISCs), security modules, etc. In at least one example, group of chiplets 103 may include one or more CPU cores 404, multiple levels of cache, memory modules, or IO controllers (e.g., as in accordance with the AMD 7000 Series Ryzen 7950X). In at least one example, group of chiplets 103 comprise heterogeneous chiplets 101 that can serve as application-specific ICs (ASICs), processor cores, field programmable gate arrays (FPGAs), serializers/deserializers (SerDes), network flow processors (NFPs), reduced instruction set computers (RISCs), or other such components.

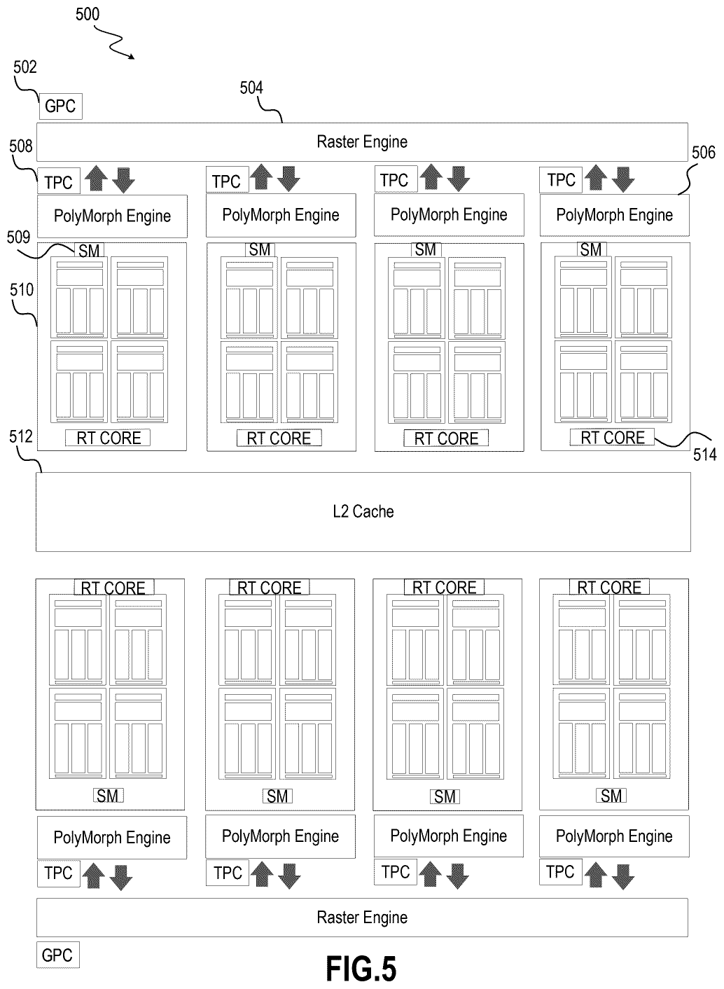

FIG. 5 is a schematic of a chiplet 500 (e.g., chiplet 406 of FIG. 4) having functionality of a GPU, in accordance with at least one example. Chiplet 500 may be one of the chiplets in a wafer-level assembly of chiplets. GPUs may handle parallel processing tasks efficiently, which may be suitable for many applications including graphics rendering, machine-learning (ML), natural language processing (NLP), or other computer-intensive applications. Chiplet 500 may include a graphics processing cluster (GPC) 502 which is a dedicated hardware block within a GPU. GPC 502 may perform functions including computing, rasterization, shading, or texturing. In at least one example, chiplet 500 includes GPC 508 which includes texture processing clusters (TPC) 508. A TPC may include a streaming multiprocessor (SM) 509 or a raster engine 504. In at least one example, this architecture allows the GPUs to handle complex graphics tasks efficiently, which can be helpful in manufacturing processes or other professional applications. In at least one example, each GPC 502 in a GPU has its own raster engine, ensuring parallel processing of graphics data. In at least one example, raster engine 504 in a GPU is responsible for converting 3D models into 2D images that can be displayed on display screen. In at least one example, raster engine 504 processes the vertices of triangles that may determine the edges or how the edges can be displayed. Raster engine 504 may remove non-visible pixels that may be behind other objects, thereby improving the rendering efficiency.

Texture Processor Cluster (TPC) 508 may enhance the GPU's ability to handle complex graphics tasks. In at least one example, each TPC 508 has multiple streaming multiprocessors (SMs) 509 responsible for executing the core computational tasks. In at least one example, SMs 509 can handle texture mapping, which may involve applying textures to 3D models. TPC 508 may manage the coordination and control of the SMs or texture units within TPC 508. TPC 508 may be grouped into larger structures called graphics processing clusters (GPCs) 502, which may further enhance the GPU's parallel processing capabilities. In at least one example, a polymorph engine 506 in a GPU is a specialized unit which handles various stages of geometry processing. In at least one example, polymorph engine 506 helps in transforming 3D models into a format that may be rasterized.

In at least one example, ray tracing cores (RT cores) 514 in the GPUs accelerate ray tracing, a rendering technique that simulates the way light interacts with objects, to produce realistic images. In at least one example, ray tracing involves navigating a hierarchical structure to determine the objects to be checked for ray intersections. RT cores 514 may check if or where a ray intersects with triangles in a 3D model, which may be essential for accurate lighting or shadow calculations. In at least one example, an L2 cache 512 in a GPU enhances performance or efficiency. L2 cache 512 might store data that may be recently used by an L1 cache or resources shared by RT cores 514. This helps in reducing the time it might take to access frequently used data. L2 cache 512 may have slightly higher latency than the L1 cache but can still be very fast. In at least one example, L2 cache 512 can act as an intermediary among the L1 cache or the main memory, can speed up data retrieval, or can reduce the need to access slower main memory. In at least one example, L2 cache 512 is shared among all SMs in the GPU thereby allowing efficient data sharing or coordination among processing units. L2 cache 512 can mediate data transfers linking the GPU or the main memory. In at least one example, L2 cache 512 helps manage the flow of data thereby providing quick data access to RT cores 514.

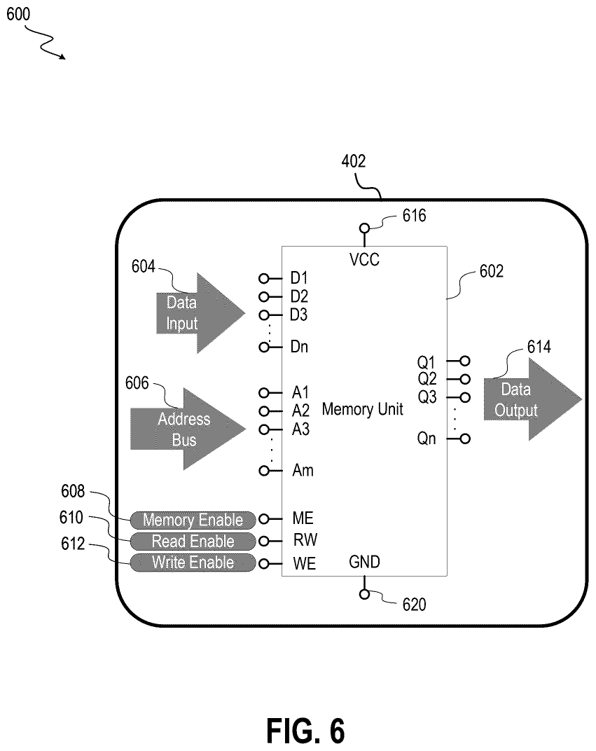

FIG. 6 is a schematic of a chiplet 600 having functionality of a memory module, in accordance with at least one example. Chiplet 600 may be one of chiplets 101 in group of chiplets 103. In at least one example, chiplet 600 includes a memory IC 602 present within memory module 402. In at least one example, memory IC 602 comprises data input pins 604, an address bus 606, data output pins 614, control signals, power supply pin (VCC) 616, or ground (GND) 620. Data input pins 604 and data output pins 614 may span from D1 to Dn. Address bus 606 may span from A1 to Am. The control signals may include a memory enable 608, read enable 610, or write enable 612. Memory enable 608 may receive an enable signal that may activate or deactivate the memory IC 602, thereby preventing unintended data access. In at least one example, memory enable 608 can also be referred to as chip enable which indicates whether chiplet 600 is active or inactive. Read enable 610, when active, may allow the data stored at a specified address in memory IC 602 to be read and sent to data output pins 614. Write enable 612 can control when the data can be written at a specified address onto memory IC 602 through data input pins 604. In at least one example, read enable 610 and write enable 612 could be merged as one, thereby combining the functionality of both control signals where a high signal may represent a data read request from memory IC 602, and a low signal may represent a data write request onto memory IC 602.

In at least one example, memory module 402 is a volatile memory used to store working data or machine code, for example, a random-access memory (RAM). The RAM could allow the data to be read and written in the same amount of time irrespective of the physical location or the size of the data. In at least one example, memory module 402 is a non-volatile memory, e.g. a read-only memory (ROM), comprising data or instructions written permanently during the manufacturing process. The ROM may be useful in storing software or data that may rarely change during the entire life of a system. In some examples, the software on ROM can be referred to as firmware such as: basic input/output system (BIOS), router firmware, smart device operating system (OS), or the like. In at least one example, the memory module 402 is an EROM (electrically rewritable ROM). The EROM is a variant of ROM that can be electrically erased and reprogrammed, thus allowing for updates during the life of the system. In at least one example, the memory module 402 is an EEPROM (electrically erasable programmable ROM). The EEPROM may be a non-volatile memory that may be electrically erased or reprogrammed along with multiple write or erase cycles. One of many of the EEPROM can have 10,000 to 100,000 write cycles. In at least one example, memory module 402 is a DRAM (Dynamic RAM). The DRAM may store each bit of data in a memory cell. The memory cell may comprise of a capacitor and a transistor. In some examples, the memory cell may comprise transistors. An external memory refresh circuitry may be used alongside DRAM, to prevent gradual capacitor leaks, which may rewrite the data on the capacitors periodically. In at least one example, the DRAM and the memory refresh circuitry is present within memory module 402. In at least one example, memory module 402 is an SRAM (static RAM). The SRAM can store each bit of data without the need of the external memory refresh circuitry. The SRAMs may be suitable for internal registers of the CPU or caches. In at least one example, memory module 402 is an SDRAM (synchronous dynamic RAM). The SDRAM operations may be coordinated with an externally supplied clock signal, which may enhance the performance by processing data in an efficient manner.

In at least one example, one or more of the DRAMs or the SDRAMs can be integrated together in memory module 402 with one or more buffers for driving the clock signal, addresses, or the control signals. In at least one example, the memory module could be implemented using stacked memory packages. The stacked memory packages can have multiple memory chips or dies. Depending on the requirement, the stacked memory packages may operate synchronously or asynchronously.

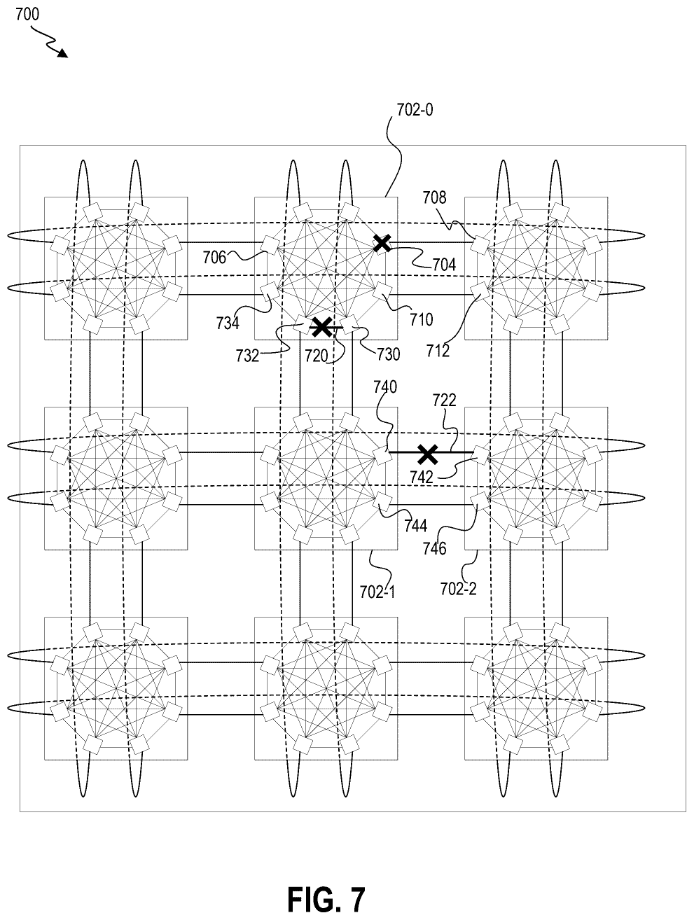

FIG. 7 is a schematic of a wafer-level assembly 700 of chiplets with redundancy, in accordance with at least one example. Redundancy mitigates failures. For instance, if one or more chiplets or one or more interconnects in wafer-level assembly 700 fails for any reason, one or more redundant chiplets or one or more redundant interconnects may be activated to replace the failed one or more chiplets or one or more interconnects. The failure of a chiplet or an interconnect may be on functional level or on bonding level. The failure of a chiplet may be at the time of manufacturing or during operation due to ageing or environmental stresses. In one example, when a chiplet 704 in a group of chiplets 702 fails to work, traffic from chiplet 706 to chiplet 708 on route 706-704-708 is rerouted on route 706-710-712-708. In another example, when interconnect 720 between a chiplet 730 and a chiplet 732 fails to work, traffic from chiplet 730 to chiplet 732 may need to be rerouted. For instance, traffic from the chiplet 730 to chiplet 732 is rerouted via chiplet 734 on route 730-734-732 instead of route 730-732.

In an example, when an intergroup interconnect 722 between a group 702-1 and a group 702-2 (e.g., interconnect between a chiplet 740 in group 702-1 and a chiplet 742 in group 702-2) fails to work, traffic from group 702-1 to group 702-1 may need to be rerouted. In at least one example, traffic from group 702-1 to group 702-1, e.g., from chiplet 740 to chiplet 742, is rerouted via route 740-744-746-742 passing through a chiplet 744 and a chiplet 746, instead to route 740-742 comprising interconnect 722.

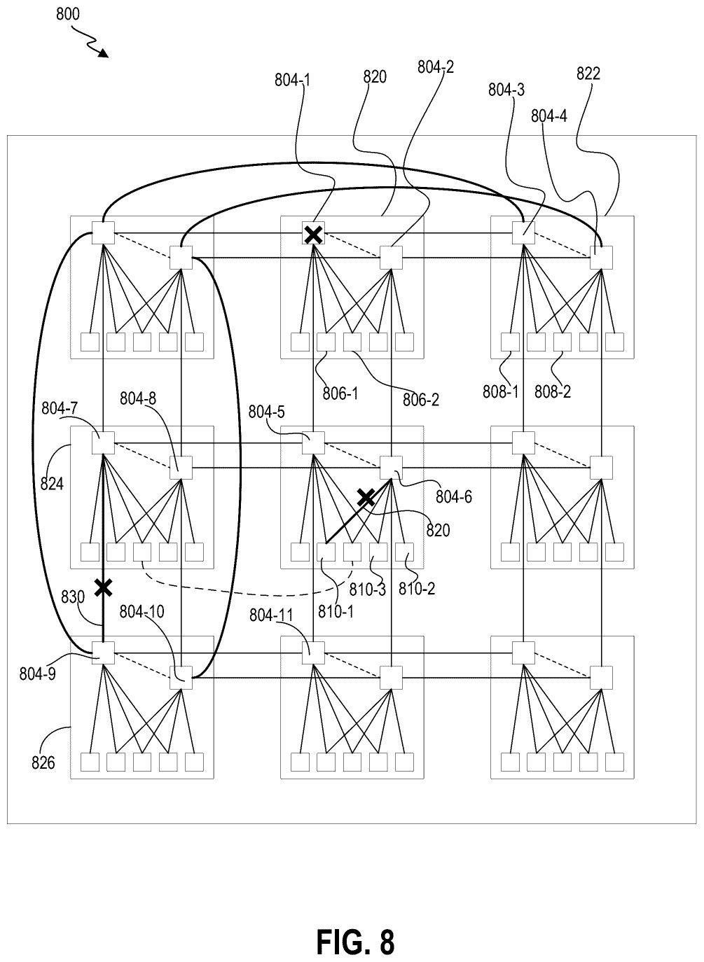

FIG. 8 is a schematic of a wafer-level assembly 800 of chiplets with redundancy, in accordance with at least one example. Wafer-level assembly 800 is another example of providing redundancy in case of failure of one or more chiplets or one or more interconnects. The failure of a chiplet or an interconnect may be on functional level or on bonding level. The failure of a chiplet may be at the time of manufacturing or during operation due to ageing or environmental stresses. In an example, when a root-chiplet 804-1 in a group of chiplets 820 fails to work, traffic from a leaf-chiplet 806-1 to a leaf-chiplet 806-2 on the route (806-1)-(804-1)-(806-2) is rerouted on route (806-1)-(804-2)-(806-2). In at least one example, traffic from a leaf-chiplet 808-1 in a group of chiplets 822 to a chiplet 806-1 is rerouted via route (808-1)-(804-3)-(808-2)-(804-4)-(804-2)-(806-1) instead of route (808-1)-(804-3)-(804-1)-(806-1).

In at least one example, interconnect 820 between a root-chiplet 804-6 and a leaf-chiplet 810-1 fails to work. Traffic from leaf-chiplet 810-1 to a leaf-chiplet 810-2 may need to be rerouted. In at least one example, the traffic from leaf-chiplet 810-1 to leaf-chiplet 810-2 is rerouted via a root-chiplet 804-5, a leaf-chiplet 810-3, and a root-chiplet 804-6 on route (810-1)-(804-5)-(810-3)-(804-6)-(810-2) instead of route (810-1)-(804-6)-(810-2).

In an example when an intergroup interconnect 830 between a group 824 and a group 826, e.g., the interconnect between a root-chiplet 804-7 in group 824 and a root-chiplet 804-9 in group 826, fails to work, traffic from group 824 to group 826 may need to be rerouted. In at least one example, traffic from group 824 to group 826, e.g., from root-chiplet 804-7 to root-chiplet 804-9 is rerouted via route (804-7)-(804-5)-804-11)-(804-9) instead to route (804-7)-(804-9) comprising of interconnect 830.

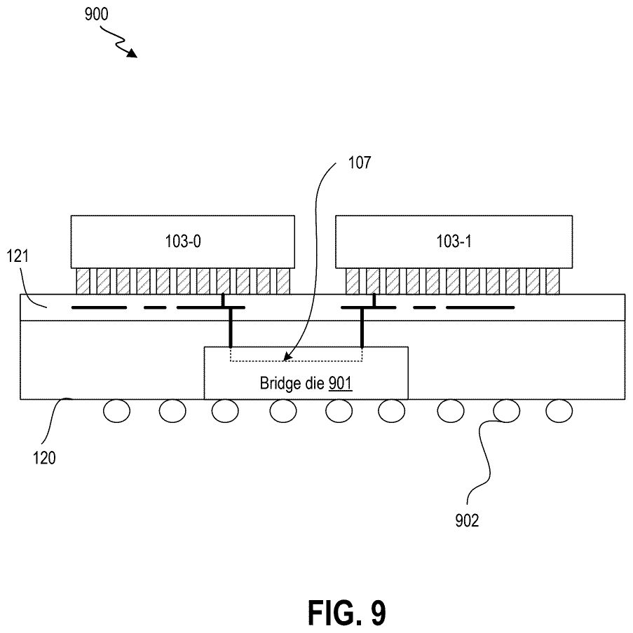

FIG. 9 is a schematic of a wafer-level assembly of chiplets 900 on a substrate with one or more bridge dies, in accordance with at least one example. In at least one example, chiplets with a group of chiplets of between groups of chiplets are interconnected via a bridge die 901 embedded in a substrate (e.g., substrate 120 or substrate 230). One such example is illustrated by FIG. 9. Here, chiplet 103-0 is interconnected to chiplet 103-1 through a metallization layer 121 which may be a redistribution layer (RDL) within the substrate. In at least one example, bridge die 901 includes drivers and switches to route signals from one end to another end. In at least one example, bridge die is a programmable die that can be programmed by hardware (e.g., fuses) or software, or a combination thereof.

In at least one example, bridge die 901 can establish electrical connections between different dies (chiplets) in a stacked or horizontally integrated configuration. In at least one example, bridge die 901 serves as an intermediary that helps reduce the distance electrical signals need to travel, improving performance and reducing latency. In at least one example, bridge die 901 can also provide interconnection outside of substrate 120 through solder bumps or package interface 902. In at least one example, bridge die 901 provides a low-resistance path for signals between chiplets and that maintains signal integrity and reduce losses. In at least one example, bridge die 901 can assist in dissipating heat across multiple chiplets, serving as a thermal interface. This helps manage heat more efficiently in wafer-level assembly of chiplet architectures. In at least one example, in a wafer-level scaling architecture, multiple types of dies (e.g., analog, digital, RF chiplets) can be integrated using bridge die 901, allowing for enhanced functionality and performance. This may be particularly valuable in applications that use diverse processing capabilities, such as internet-of-things (IoT) devices or mobile applications. In at least one example, bridge die 901 allows for a more compact design by reducing the overall footprint of the wafer-level assembly. For instance, by layering dies and connecting them with bridge die 901, manufacturers can save space on substrate 120.

By integrating bridge dies such as bridge die 901 at the wafer level, manufacturers can achieve higher yields and better cost efficiency. Defects in one die can be mitigated by the presence of bridge die 901, allowing the use of more dies from the same wafer assembly. The inclusion of bridge dies provides designers with more flexibility, enabling a modular approach to building complex systems. This allows for easier upgrades or changes in design over time. Bridge die 901 can be used with any wafer-level assembly of chiplets discussed herein. While FIG. 9 illustrates one bridge die 901 partially between chiplet 103-0 is and chiplet 103-1, similar bridge dies can be used to couple other chiplets. In at least one example, every two chiplets share a bridge die. In at least one example, every four chiplets share a bridge die. In other examples, any number of chiplets may share a bridge die.

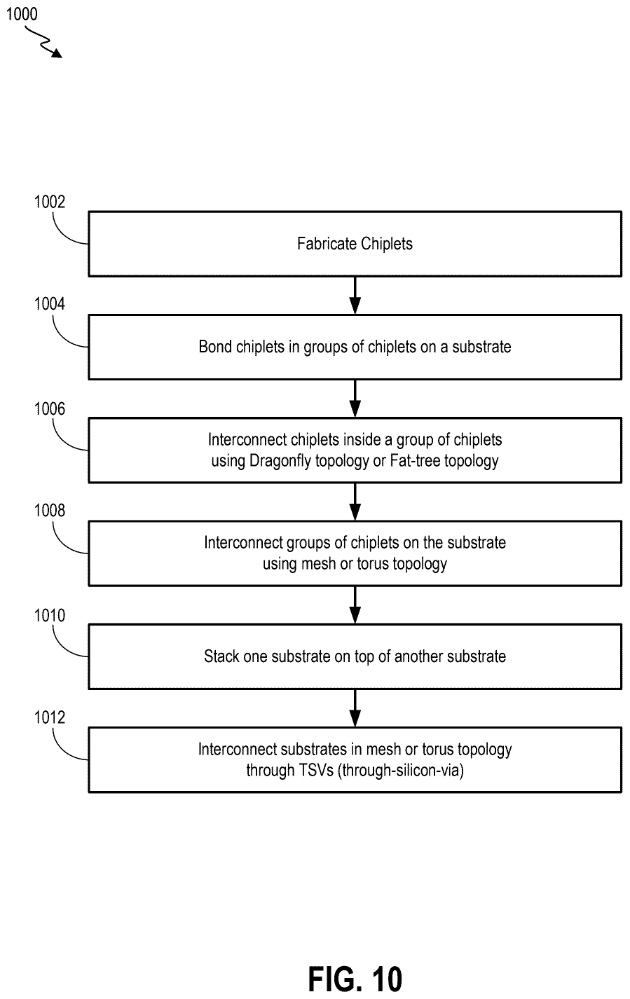

FIG. 10 is a flowchart 1000 of a method of fabricating a wafer-level assembly of chiplets with redundancy, in accordance with at least one example. While various blocks are shown in a particular order, the order can be modified. For instance, some blocks may be performed before others while some blocks may be performed in parallel.

At block 1002, chiplets (e.g., chiplets 101) are fabricated using any of the available state-of-the-art techniques. The chiplets may be manufactured using different technologies, for example, CMOS or TTL. The chiplets may have the same functionality, for example, all chiplets may be microprocessors, memory modules, GPUs, communication ports, or sensors. The chiplets may also be functionally different, for example, chiplets may be a mix of microprocessors, memory modules, GPUs, communication ports, or sensors.

At block 1004, chiplets are bonded on a substrate (e.g., substrate 120 or substrate 230). The substrate may be organic or silicon. The substrate may also be an interposer comprising active components. Interconnect wires, for example, 105-0 or 214-0 etc., may be grown on or inside the substrate.

At block 1006, groups of chiplets, for example, group of chiplets 103-0 or group of chiplets 204-0, etc., are formed on the substrate to make a wafer-level assembly, for example, wafer-level assembly 100 or the wafer-level assembly 200. The interconnections between chiplets inside a group may be in fully-connected topology, for example, interconnects 105, or in a fat-tree topology, for example, interconnects 210.

At block 1008, groups of chiplets in the wafer-level assembly on the substrate are connected in a mesh or torus topology, for example, wafer-level assembly 100 or wafer-level assembly 200.

At block 1010, the wafer-level assemblies are stacked in 3D on top of each other, for example, as shown in schematic 300. At block 1012, vertical interconnections between groups of chiplets in each layer are provided using TSVs (through-silicon-via), for example, TSV 302-0. The interconnects between substrates of different layers may be in mesh or torus topology.

Here, “device,” “node,” or “unit” may generally refer to an apparatus according to the context of the usage of that term. For example, a device may refer to a stack of layers or structures, a single structure or layer, a connection of various structures having active and/or passive elements, etc. Generally, a device is a three-dimensional structure with a plane along the x-y direction and a height along the z direction of an x-y-z Cartesian coordinate system. The plane of the device may also be the plane of an apparatus, which comprises the device.

Throughout the specification, and in the claims, the term “connected” means a direct connection, such as electrical, mechanical, or magnetic connection between the things that are connected, without any intermediary devices.

The term “coupled” means a direct or indirect connection, such as a direct electrical, mechanical, or magnetic connection between the things that are connected or an indirect connection, through one or more passive or active intermediary devices.

The term “adjacent” here generally refers to a position of a thing being next to (e.g., immediately next to or close to with one or more things between them) or adjoining another thing (e.g., abutting it).

The term “circuit” or “module” may refer to one or more passive and/or active components that are arranged to cooperate with one another to provide a desired function.

The term “signal” may refer to at least one current signal, voltage signal, magnetic signal, or data/clock signal. The meaning of “a,” “an,” and “the” include plural references. The meaning of “in” includes “in” and “on.”

Here, the term “analog signal” generally refers to any continuous signal for which the time varying feature (variable) of the signal is a representation of some other time varying quantity, i.e., analogous to another time varying signal.

Here, the term “digital signal” generally refers to a physical signal that is a representation of a sequence of discrete values (a quantified discrete-time signal), for example of an arbitrary bit stream, or of a digitized (sampled and analog-to-digital converted) analog signal.

The term “scaling” generally refers to converting a design (schematic and layout) from one process technology to another process technology and subsequently being reduced in layout area. The term “scaling” generally also refers to downsizing layout and devices within the same technology node. The term “scaling” may also refer to adjusting (e.g., slowing down or speeding up—i.e., scaling down, or scaling up respectively) of a signal frequency relative to another parameter, for example, power supply level.

The terms “substantially,” “close,” “approximately,” “near,” and “about,” generally refer to being within +/−10% of a target value. For example, unless otherwise specified in the explicit context of their use, the terms “substantially equal,” “about equal” and “approximately equal” mean that there is no more than incidental variation between among things so described. In the art, such variation is typically no more than +/−10% of a predetermined target value.

Unless otherwise specified the use of the ordinal adjectives “first,” “second,” and “third,” etc., to describe a common object, merely indicate that different instances of like objects are being referred to and are not intended to imply that the objects so described must be in a given sequence, either temporally, spatially, in ranking or in any other manner.

For the purposes of the present disclosure, phrases “A and/or B” and “A or B” mean (A), (B), or (A and B). For the purposes of the present disclosure, the phrase “A, B, and/or C” means (A), (B), (C), (A and B), (A and C), (B and C), or (A, B and C).

The terms “left,” “right,” “front,” “back,” “top,” “bottom,” “over,” “under,” and the like in the description and in the claims, if any, are used for descriptive purposes and not necessarily for describing permanent relative positions. For example, the terms “over,” “under,” “front side,” “back side,” “top,” “bottom,” “over,” “under,” and “on” as used herein refer to a relative position of one component, structure, or material with respect to other referenced components, structures or materials within a device, where such physical relationships are noteworthy. These terms are employed herein for descriptive purposes only and predominantly within the context of a device z-axis and therefore may be relative to an orientation of a device.

Reference in the specification to “an example,” “one example,” “some examples,” or “other examples” means that a particular feature, structure, or characteristic described in connection with the examples is included in at least some examples, but not necessarily all examples. The various appearances of “an example,” “one example,” or “some examples” are not necessarily all referring to the same examples. If the specification states a component, feature, structure, or characteristic “may,” “might,” or “could” be included, that particular component, feature, structure, or characteristic is not required to be included. If the specification or claim refers to “a” or “an” element, that does not mean there is only one of the elements. If the specification or claims refer to “an additional” element, that does not preclude there being more than one of the additional elements.

Furthermore, the particular features, structures, functions, or characteristics may be combined in any suitable manner in one or more examples. For example, a first example may be combined with a second example anywhere the particular features, structures, functions, or characteristics associated with the two examples are not mutually exclusive.

While the disclosure has been described in conjunction with specific examples thereof, many alternatives, modifications and variations of such examples will be apparent to those of ordinary skill in the art in light of the foregoing description. The examples of the disclosure are intended to embrace all such alternatives, modifications, and variations as to fall within the broad scope of the appended claims.

In addition, well-known power/ground connections to IC chips and other components may or may not be shown within the presented figures, for simplicity of illustration and discussion, and so as not to obscure the disclosure. Further, arrangements may be shown in block diagram form to avoid obscuring the disclosure, and also in view of the fact that specifics with respect to implementation of such block diagram arrangements are highly dependent upon the platform within which the present disclosure is to be implemented (i.e., such specifics should be well within purview of one skilled in the art). Where specific details (e.g., circuits) are set forth to describe examples of the disclosure, it should be apparent to one skilled in the art that the disclosure can be practiced without, or with variation of, these specific details. The description is thus to be regarded as illustrative instead of limiting.

The structures of various examples described herein can also be described as method(s) of forming those structures or apparatuses, and method(s) of operation of these structures or apparatuses. The following examples are provided that illustrate the various examples of the disclosure. The examples can be combined with other examples. As such, various examples can be combined with other examples without changing the scope of the invention.

Example 1 is a wafer-level assembly of chiplets comprising: a plurality of groups of chiplets including a first group of chiplets and a second group of chiplets, wherein the first group of chiplets is organized as a first fully-connected configuration, wherein the second group of chiplets is organized as a second fully-connected configuration; and a plurality of interconnects including a first interconnect and a second interconnect, wherein the first interconnect couples a first chiplet of the first group of chiplets with a first chiplet of the second group of chiplets, wherein the second interconnect couples a second chiplet of the first group of chiplets with a second chiplet of the second group of chiplets, and wherein the plurality of interconnects is arranged in a mesh configuration.

Example 2 is a wafer-level assembly of chiplets according to any example herein, in particular example 1, further comprising a substrate, wherein the plurality of groups of chiplets is on the substrate, wherein the substrate includes a redistribution layer.

Example 3 is a wafer-level assembly of chiplets according to any example herein, in particular example 2, wherein the plurality of interconnects is in the substrate.

Example 4 is a wafer-level assembly of chiplets according to any example herein, in particular example 2, wherein the plurality of interconnects is on the substrate.

Example 5 is a wafer-level assembly of chiplets according to any example herein, in particular example 1, further comprising a substrate, wherein the plurality of groups of chiplets is on the substrate, and wherein the substrate includes a bridge die which is at least partially under the first group of chiplets and the second group of chiplets.

Example 6 is a wafer-level assembly of chiplets according to any example herein, in particular example 1, wherein the plurality of groups of chiplets is a first plurality of groups of chiplets, wherein the wafer-level assembly of chiplets comprises a second plurality of groups of chiplets including a third group of chiplets and a fourth group of chiplets, wherein the third group of chiplets is organized as a third fully-connected configuration, wherein the fourth group of chiplets is organized as a fourth fully-connected configuration, and wherein first plurality of groups of chiplets is below the second plurality of groups of chiplets.

Example 7 is a wafer-level assembly of chiplets according to any example herein, in particular example 6, wherein groups of chiplets in the first plurality of groups of chiplets are arranged in a first torus configuration, and wherein groups of chiplets in the second plurality of groups of chiplets are arranged in a second torus configuration.

Example 8 is a wafer-level assembly of chiplets according to any example herein, in particular example 6, wherein the second plurality of groups of chiplets and the first plurality of groups of chiplets are coupled in a third torus configuration.

Example 9 is a wafer-level assembly of chiplets according to any example herein, in particular example 6, wherein the plurality of interconnects is a first plurality of interconnects, wherein wafer-level assembly of chiplets further comprising a second plurality of interconnects including a third interconnect and a fourth interconnect, wherein the third interconnect couples a third chiplet of the third group of chiplets with a third chiplet of the fourth group of chiplets, wherein the fourth interconnect couples a fourth chiplet of the third group of chiplets with a fourth chiplet of the fourth group of chiplets, and wherein the plurality of interconnects is arranged in a mesh configuration.

Example 10 is a wafer-level assembly of chiplets according to any example herein, in particular example 1, wherein the first group of chiplets includes at least two identical chiplets.

Example 11 is a wafer-level assembly of chiplets according to any example herein, in particular example 1, wherein plurality of groups of chiplets are arranged in a torus configuration.

Example 12 is a wafer-level assembly of chiplets comprising: a plurality of groups of chiplets including a first group of chiplets and a second group of chiplets, wherein the first group of chiplets is organized as a first fat-tree configuration, wherein the second group of chiplets is organized as a second fat-tree configuration; and a plurality of interconnects including a first interconnect and a second interconnect, wherein the first interconnect couples a first root-chiplet of the first group of chiplets with a first root-chiplet of the second group of chiplets, wherein the second interconnect couples a second root-chiplet of the first group of chiplets with a second root-chiplet of the second group of chiplets, and wherein the plurality of interconnects is arranged in a mesh configuration.

Example 13 is a wafer-level assembly of chiplets according to any example herein, in particular example 12 further comprising a substrate, wherein the plurality of groups of chiplets is on the substrate, wherein the substrate includes a redistribution layer.

Example 14 is a wafer-level assembly of chiplets according to any example herein, in particular example 13, wherein the plurality of interconnects is in the substrate.

Example 15 is a wafer-level assembly of chiplets according to any example herein, in particular example 13, wherein the plurality of interconnects is on the substrate.

Example 16 is a wafer-level assembly of chiplets according to any example herein, in particular example 12, further comprising a substrate, wherein the plurality of groups of chiplets is on the substrate, and wherein the substrate includes a bridge die which is at least partially under the first group of chiplets and the second group of chiplets.

Example 17 is a wafer-level assembly of chiplets according to any example herein, in particular example 13, wherein the plurality of groups of chiplets is a first plurality of groups of chiplets, wherein the wafer-level assembly of chiplets comprises a second plurality of groups of chiplets including a third group of chiplets and a fourth group of chiplets, wherein the third group of chiplets is organized as a third fat-tree configuration, wherein the fourth group of chiplets is organized as a fourth fat-tree configuration, and wherein first plurality of groups of chiplets is below the second plurality of groups of chiplets.

Example 18 is a wafer-level assembly of chiplets according to any example herein, in particular example 17, wherein groups of chiplets in the first plurality of groups of chiplets are arranged in a first torus configuration, wherein groups of chiplets in the second plurality of groups of chiplets are arranged in a second torus configuration.

Example 19 is a wafer-level assembly of chiplets according to any example herein, in particular example 18, wherein the second plurality of groups of chiplets and the first plurality of groups of chiplets are coupled in a third torus configuration.

Example 20 is a wafer-level assembly of chiplets according to any example herein, in particular example 18, wherein the plurality of interconnects is a first plurality of interconnects, wherein wafer-level assembly of chiplets further comprising a second plurality of interconnects including a third interconnect and a fourth interconnect, wherein the third interconnect couples a third root-chiplet of the third group of chiplets with a third root-chiplet of the fourth group of chiplets, wherein the fourth interconnect couples a fourth root-chiplet of the third group of chiplets with a fourth root-chiplet of the fourth group of chiplets, wherein the plurality of interconnects is arranged in a mesh configuration.

Example 21 is a wafer-level assembly of chiplets according to any example herein, in particular example 12, wherein the first group of chiplets includes at least two identical chiplets.

Example 22 is a wafer-level chip assembly comprising: a plurality of groups of dies including a first group of dies and a second group of dies, wherein the first group of dies is organized as a first full-connected configuration, wherein the second group of dies is organized as a second full-connected configuration; and a plurality of interconnects including a first interconnect and a second interconnect, wherein the first interconnect couples a first die of the first group of dies with a first die of the second group of dies, wherein the second interconnect couples a second die of the first group of dies with a second die of the second group of dies, and wherein the plurality of interconnects is arranged in a mesh configuration.

Example 22 is a wafer-level chip assembly according to any example herein, in particular example 22, further comprising a substrate, wherein the plurality of groups of dies is on the substrate, and wherein the substrate includes a bridge die which is at least partially under the first group of dies and the second group of dies.

What is claimed is:

1. A wafer-level assembly of chiplets comprising:
a plurality of groups of chiplets including a first group of chiplets and a second group of chiplets, wherein the first group of chiplets is organized as a first fully-connected configuration, wherein the second group of chiplets is organized as a second fully-connected configuration; and
a plurality of interconnects including a first interconnect and a second interconnect, wherein the first interconnect couples a first chiplet of the first group of chiplets with a first chiplet of the second group of chiplets, wherein the second interconnect couples a second chiplet of the first group of chiplets with a second chiplet of the second group of chiplets, and wherein the plurality of interconnects is arranged in a mesh configuration.

2. The wafer-level assembly of chiplets of claim 1 further comprising a substrate, wherein the plurality of groups of chiplets is on the substrate, wherein the substrate includes a redistribution layer.

3. The wafer-level assembly of chiplets of claim 2, wherein the plurality of interconnects is in the substrate.

4. The wafer-level assembly of chiplets of claim 2, wherein the plurality of interconnects is on the substrate.

5. The wafer-level assembly of chiplets of claim 1, further comprising a substrate, wherein the plurality of groups of chiplets is on the substrate, and wherein the substrate includes a bridge die which is at least partially under the first group of chiplets and the second group of chiplets.

6. The wafer-level assembly of chiplets of claim 1, wherein the plurality of groups of chiplets is a first plurality of groups of chiplets, wherein the wafer-level assembly of chiplets comprises a second plurality of groups of chiplets including a third group of chiplets and a fourth group of chiplets, wherein the third group of chiplets is organized as a third fully-connected configuration, wherein the fourth group of chiplets is organized as a fourth fully-connected configuration, and wherein first plurality of groups of chiplets is below the second plurality of groups of chiplets.

7. The wafer-level assembly of chiplets of claim 6, wherein groups of chiplets in the first plurality of groups of chiplets are arranged in a first torus configuration, and wherein groups of chiplets in the second plurality of groups of chiplets are arranged in a second torus configuration.

8. The wafer-level assembly of chiplets of claim 6, wherein the second plurality of groups of chiplets and the first plurality of groups of chiplets are coupled in a third torus configuration.

9. The wafer-level assembly of chiplets of claim 6, wherein the plurality of interconnects is a first plurality of interconnects, wherein wafer-level assembly of chiplets further comprising a second plurality of interconnects including a third interconnect and a fourth interconnect, wherein the third interconnect couples a third chiplet of the third group of chiplets with a third chiplet of the fourth group of chiplets, wherein the fourth interconnect couples a fourth chiplet of the third group of chiplets with a fourth chiplet of the fourth group of chiplets, and wherein the plurality of interconnects is arranged in a mesh configuration.

10. The wafer-level assembly of chiplets of claim 1, wherein the first group of chiplets includes at least two identical chiplets.

11. The wafer-level assembly of chiplets of claim 1, wherein plurality of groups of chiplets are arranged in a torus configuration.

12. A wafer-level assembly of chiplets comprising:
a plurality of groups of chiplets including a first group of chiplets and a second group of chiplets, wherein the first group of chiplets is organized as a first fat-tree configuration, wherein the second group of chiplets is organized as a second fat-tree configuration; and
a plurality of interconnects including a first interconnect and a second interconnect, wherein the first interconnect couples a first root-chiplet of the first group of chiplets with a first root-chiplet of the second group of chiplets, wherein the second interconnect couples a second root-chiplet of the first group of chiplets with a second root-chiplet of the second group of chiplets, and wherein the plurality of interconnects is arranged in a mesh configuration.

13. The wafer-level assembly of chiplets of claim 12 further comprising a substrate, wherein the plurality of groups of chiplets is on the substrate, wherein the substrate includes a redistribution layer.

14. The wafer-level assembly of chiplets of claim 13, wherein the plurality of interconnects is in the substrate.

15. The wafer-level assembly of chiplets of claim 13, wherein the plurality of interconnects is on the substrate.

16. The wafer-level assembly of chiplets of claim 12, further comprising a substrate, wherein the plurality of groups of chiplets is on the substrate, and wherein the substrate includes a bridge die which is at least partially under the first group of chiplets and the second group of chiplets.

17. The wafer-level assembly of chiplets of claim 13, wherein the plurality of groups of chiplets is a first plurality of groups of chiplets, wherein the wafer-level assembly of chiplets comprises a second plurality of groups of chiplets including a third group of chiplets and a fourth group of chiplets, wherein the third group of chiplets is organized as a third fat-tree configuration, wherein the fourth group of chiplets is organized as a fourth fat-tree configuration, and wherein first plurality of groups of chiplets is below the second plurality of groups of chiplets.

18. The wafer-level assembly of chiplets of claim 17, wherein groups of chiplets in the first plurality of groups of chiplets are arranged in a first torus configuration, wherein groups of chiplets in the second plurality of groups of chiplets are arranged in a second torus configuration.

19. The wafer-level assembly of chiplets of claim 18, wherein the second plurality of groups of chiplets and the first plurality of groups of chiplets are coupled in a third torus configuration.

20. The wafer-level assembly of chiplets of claim 18, wherein the plurality of interconnects is a first plurality of interconnects, wherein wafer-level assembly of chiplets further comprising a second plurality of interconnects including a third interconnect and a fourth interconnect, wherein the third interconnect couples a third root-chiplet of the third group of chiplets with a third root-chiplet of the fourth group of chiplets, wherein the fourth interconnect couples a fourth root-chiplet of the third group of chiplets with a fourth root-chiplet of the fourth group of chiplets, wherein the plurality of interconnects is arranged in a mesh configuration.

21. The wafer-level assembly of chiplets of claim 12, wherein the first group of chiplets includes at least two identical chiplets.

22. A wafer-level chip assembly comprising:
a plurality of groups of dies including a first group of dies and a second group of dies, wherein the first group of dies is organized as a first full-connected configuration, wherein the second group of dies is organized as a second full-connected configuration; and
a plurality of interconnects including a first interconnect and a second interconnect, wherein the first interconnect couples a first die of the first group of dies with a first die of the second group of dies, wherein the second interconnect couples a second die of the first group of dies with a second die of the second group of dies, and wherein the plurality of interconnects is arranged in a mesh configuration.

23. The wafer-level chip assembly of claim 22, further comprising a substrate, wherein the plurality of groups of dies is on the substrate, and wherein the substrate includes a bridge die which is at least partially under the first group of dies and the second group of dies.
